(19) United States
(12) Patent Application Publication
(10) Pub. No.: US 2013/0270984 A1
(43) Pub. Date: Oct. 17, 2013

(54) STORAGE UNIT

(71) Applicant: Shinichi Chuda, Tokyo (JP)

(72) Inventor: Shinichi Chuda, Tokyo (JP)

(73) Assignee: MITSUBISHI HEAVY INDUSTRIES, LTD., Tokyo (JP)

(21) Appl. No.: 13/990,272

(22) PCT Filed: Jul. 20, 2012
(86) PCT No.: PCT/JP2012/068449

§ 371 Date: May 29, 2013

(30) Foreign Application Priority Data
Jul. 29, 2011 (JP) 2011-167546

(51) Int. Cl. A47B 96/00; H05K 7/20

(52) U.S. Cl. CPC A47B 96/00; H05K 7/20
USPC 312/236; 312/348.3

(57) ABSTRACT

A storage unit includes a first drawer having a first drawer front plate; a second drawer having a second drawer front plate; a housing having a partition plate for partitioning a first compartment into which the first drawer is inserted and a second compartment into which the second drawer is inserted; and fixing means. The first drawer front plate and the second drawer front plate alternately lit each other over the partition plate but do not overlap each other over the partition plate, and the first drawer front plate and the second drawer front plate are respectively fixed to the housing on both sides of the first compartment or on both sides of the second compartment, using the fixing means.

### TECHNICAL FIELD

The present iavention relates to a storage unit equipped with a plurality of drawers.

Priority is claimed on Japanese Patent Application No. 2011-167546, filed Jul. 29, 2011, the content of which is incorporated herein by reference.

### BACKGROUND ART

Conventionally, storage units (refer to PATENT DOCUMENT 1 and PATENT DOCUMENT 2) equipped with a plurality of drawers include a plurality of drawers and a housing provided with a plurality of compartments that store these drawers, respectively. For example, as shown in FIGS. 5A and 5B, a storage unit is constructed by a plurality of drawers (a drawer is shown in FIG. 5B) of the same shape and the same dimension, and a housing (refer to FIG. 5A) in which a plurality of compartments for storing these drawers are arranged in a matrix of 3 rows and 3 columns.

In order to prevent these drawers from coming out of the corresponding compartments when there is earthquake, vibration, or the like according to places where this storage unit is installed and to prevent the contents of the drawers from spilling out of the storage unit, a structure in which the respective drawers and housing are fixed with screws may be taken (refer to PATENT DOCUMENT 1).

### CITATION LIST

### Patent Literature

[PATENT DOCUMENT 1] Japanese Unexamined Patent Application, First Publication No. 2001-137052

[PATENT DOCUMENT 2] Japanese Unexamined Patent Application, First Publication No. 2000-223867

### SUMMARY OF INVENTION

### Technical Problem

However, in the storage unit of the related art, in order to fix drawer screw holes 23 provided in front plates of the drawers and housing screw holes 14 provided in the housing with male screws, one row of housing screw holes 14 are arranged in a vertical direction (Z-direction) respectively (refer to FIG. 5A) on both sides of the compartments of each column, respectively. In other words, two rows of screw holes are arranged in a vertical direction (Z-direction) at a predetermined interval in a width direction (X-direction) between the compartments of columns adjacent to each other in the housing.

One row of housing screw holes 14 are arranged on both sides of the compartments of each column, respectively, in order to fix the front plates of the drawers to the housing on both sides of the compartments corresponding to the drawers. This configuration is one of the most effective fixing methods in preventing the drawers from coming out of the corresponding compartments and to prevent the contents of the drawers from spilling ottt of the storage unit, as described above.

For this reason, the conventional storage unit has limitations in making the interval between the compartments of columns adjacent to each other small while adopting a fixing member that fixes the front plates of the drawers to the housing on both sides of the compartments corresponding to the drawers, using screws of the same dimensions as the drawer screw holes 23 and the housing screw holes 14. As a result, it is difficult to achieve size reduction of the storage unit without changing the capacity of the drawers.

The present invention has been made in view of this situation, and an object thereof is to provide a storage unit whose size reduction is enabled by making the interval between compartments of columns adjacent to each other small while adopting a fixing member that fixes frost plates of drawers to a housing on both sides of compartments corresponding to the drawers.

### Solution to Problem

According to a first aspect of the present invention, there is provided a storage unit including a first drawer having a first drawer front plate; a second drawer having a second drawer front plate; a housing having a partition plate for partitioning a first compartment into which the first drawer is inserted and a second compartment into which the second drawer is inserted; and a fixing member. The first drawer front plate and the second drawer front plate alternately fit each other on the partition plate and are arranged on partition plate without overlapping, and the first drawer front plate and the second drawer front plate are respectively fixed to the housing on both sides of the first compartment or on both sides of the second compartment, using the fixing member.

According to the above, since the first drawer front plate and second drawer front plate are adapted to alternately fit each other over the partition plate, the interval between the first compartment and the second compartment, that is, the thickness of the partition plate that partitions these compartments can be made small compared to the conventional partition plate. Moreover, it is possible to fix the first drawer front plate on both sides of the first compartment by the fixing member and to fix the second drawer front plate on both sides of the second compartment by the fixing member.

### Advantageous Effects of Invention

According to the above, it is possible to provide a storage unit in which size reduction is enabled without changing the amount of the drawers from the amount of the drawers of the storage unit of the related art by making the interval between the compartments of columns adjacent to each other small while fixing the front plates of the drawers to the housing on both sides of the compartments corresponding to the drawers.

### BRIEF DESCRIPTION OF DRAWINGS

FIG. 1 is a schematic view (front view) of a storage onit related to an

embodiment of the present invention.

FIG. 2 is a schematic view (perspective view) stowing a housing (a storage unit in a state where all drawers are removed) of the storage unit of FIG 1.

FIG. 3A is a perspective view showing a schematic view of one drawer of the storage unit of FIG. 1.

FIG. 3B is a top view showing a schematic view of one drawer of the storage unit of FIG 1.

FIG. 4A is a schematic view showing a front plate of the drawer of FIG 3A.

FIG. 4B is a schematic view showing a modified example of the front plate of the drawer.

FIG. 4C is a schematic view showing a modified example of the front plate of the drawer.

FIG. 4D is a schematic view showing a modified example of the front plate of the drawer.

FIG. 5A is a schematic view (perspective view) of a housing (a storage unit in a state where all drawers are removed) of the storage unit.

FIG. 5B is a schematic view (perspective view) of a drawer of the storage unit.

### DESCRIPTION OF EMBODIMENTS

A storage unit related to an embodiment of the present invention shown below has a shape in which drawer front plates of two drawers, which are adjacent to each other across a partition plate that partitions compartments among a plurality of drawers respectively inserted into the corresponding compartments of a housing, alternately fit each other over the partition plate or are alternately combined with each other over the partition plate, and the drawer front plates do not overlap each other over the partition plate. Thereby, the storage unit has a feature that the respective drawer front plates can be fixed to the housing on both sides of the compartments corresponding to the respective drawers, and size reduction is enabled. Hereinafter, detailed description will be made referring to the drawings.

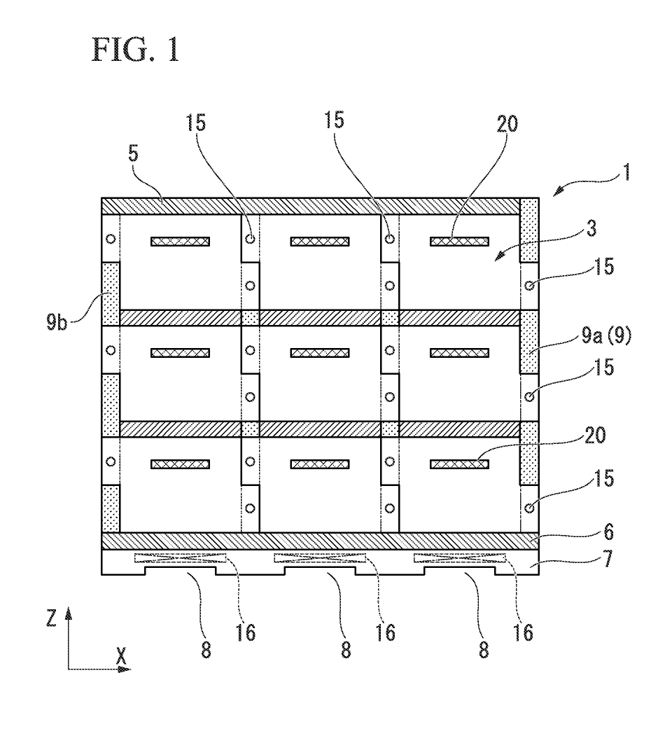

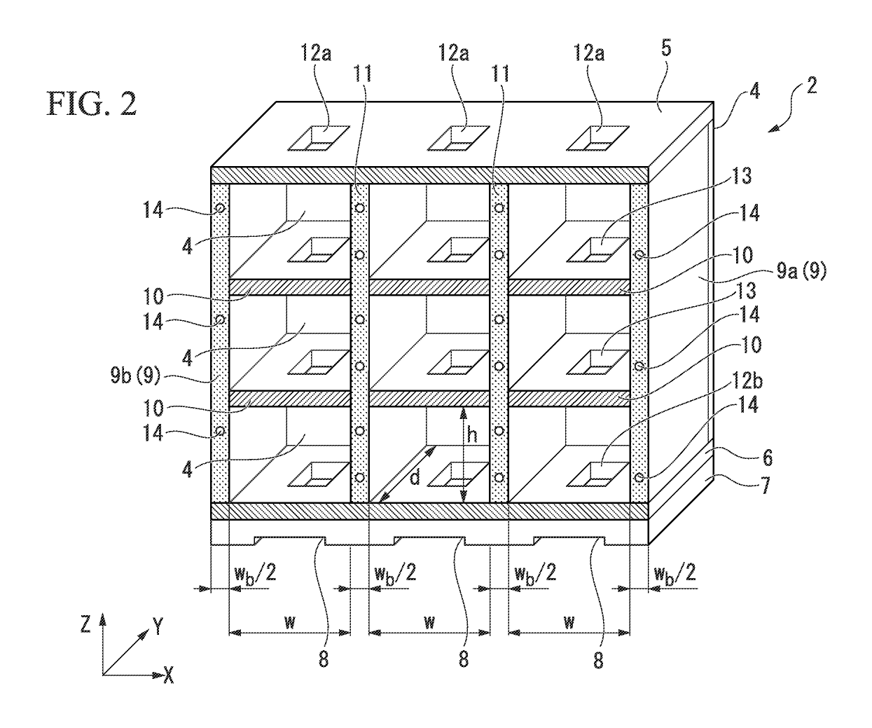

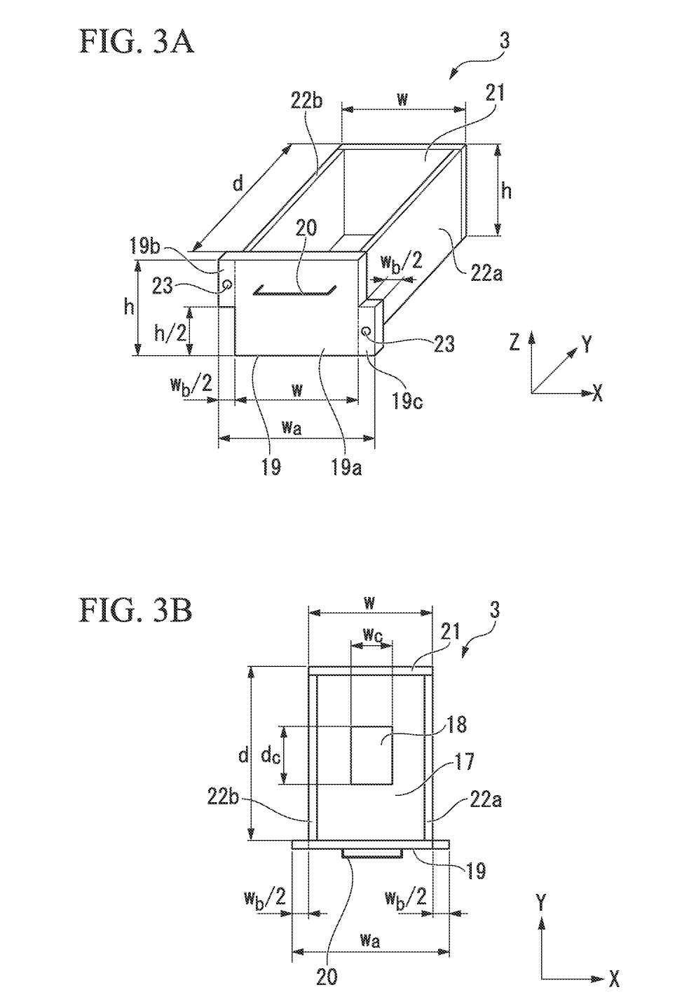

FIG. 1 is a schematic view showing the configuration of a storage unit 1 of the embodiment of the present invention. Additionally, FIG. 2 is a schematic view showing only a housing 2 of the storage trait 1 of FIG. 1, and FIG. 3A and FIG. 3B are schematic views showing an example of a drawer 3 of the storage unit 1 of FIG. 1. In addition, in a case where XYZ direct coordinate systems are shown in the drawings shown below, all of them are the same orthogonal coordinate systems. Additionally, all of wₐ, w_{b}, w_{c}, w, h, D, d, and d_{c} that are shown as dimensions below are positive real numbers.

As shown in FIGS. 1 and 2, the storage unit 1 includes a housing 2 in which diree rectangular-parallelepiped compartments that open in a −Y-direction are arranged in a height direction (+Z-direction) and three rectangular-parallelepiped compartments that open in the −Y-direction are arranged in a width direction (X-direction), that is, the housing 2 including a plurality of compartments (a first compartment, a second compartment adjacent to the first compartment, and a third compartment arranged continuously with the first compartment) of the substantially same dimensions that are orderly arranged as a matrix of 3 rows×3 columns, and rectangular-parallelepiped drawers 3 (a first drawer, a second drawer, and a third drawer) that are arranged in the compartments, respectively, and are inserted in a +Y direction from the openings of the compartments, to close the openings.

Here, there is shown an example in which the storage unit 1 includes a “chimney-like passage” to be described blow, in every column where a plurality of compartments are arranged, in order to suppose that heating elements, such as electronic devices, for example, a battery module or an electric circuit, are stored in the drawers 3 as contents, and the temperature of the electronic devices are effectively controlled (for example, cooled).

The housing 2 includes a hack plate 4, a top plate 5, a bottom plate 6, a side plate 9a, and a side plate 9b in order to form the above plurality of compartments.

The back plate 4 has a predetermined thickness, and has a substantially rectangular shape as viewed from an XZ plane. The top plate 5 has a predetermined thickness, has a substantially rectangular shape as viewed from an XY plane, and is connected to one side located on +Z-direction side out of two sides of the back plate 4 that extend in the X-direction.

Additionally, vent holes (first vent holes) 12a of the same shape and structure as vent holes 13 to be described below are respectively formed at positions corresponding to the above three compartments with which the top plate 5 have contact, in the top plate 5.

The bottom plate 6 has the same dimensions as the top plate 5, and is connected to one side located on −Z-direction side out of two sides of the back plate 4 that extend in the X-direction. In addition, vent holes (first vent holes) 12b of the same shape and structure as the vent holes 13 to be described below are respectively formed at positions corresponding to the above three compartments with which the bottom plate 6 have contact, in the bottom plate 6.

The side plate 9a has a predetermined thickness, has a substantially rectangular shape as viewed from a YZ plane, and is connected to one side located on +X-direction side out of two sides of the back plate 4 that extend in a Z-direction and to one side located on the +X-direction side out of two sides of the top plate 5 and the bottom plate 6 that extend in the Y-direction, respectively.

The side plate 9b has a predetermined thickness, has a substantially rectangular shape as viewed from the YZ plane, and is connected to one side located on −X-direction side out of the two sides of the back plate 4 that extend in the Z-direction and to one side located on the −X-direeiion side out of the two sides of the top plate 5 and the bottom plate 6 that extend in the Y-direction, respectively.

Additionally, the housing 2 includes first partition plates (partition plates) 10 and second partition plates (partition plates) 11 to be described next in order to partition an inner space of a configuration (referred to as an “outer frame” of the housing 2) in which the back plate 4, the top plate 5, the bottom plate 6, and the two side plates 9 (side plates 9a and 9b) are connected to each other as described above, in a 3×3 matrix, to form the above nine compartments.

Moreover, the housing 2 includes a platform 7 that supports the outer frame of the housing 2 and in which three blowers 16 and three vent holes 8 corresponding to the respective columns are arranged, in order to send a fluid, such as air or rare gas, into the above compartments of the respective three columns from the three vent holes 12b of the bottom plate 6, respectively. The vent holes 8 are appropriately designed so that the above fluid can freely flow from the outside of the housing 2 into the inside thereof or froin the inside of the housing into the outside thereof. Here, the vent holes 8 are provided as substantially rectangular cutouts provided in the platform 7.

The first partition plates 10 are bottom plates or top plates of the above compartments, have a predetermined thickness, and have a substantially rectangular shape as viewed from the XY plane. As shown in FIG. 2, the vent holes 13 that pass through the first partition plates 10 are formed in the first partition plates 10 in order to promote ventilation of each of the above compartments. Here, the vent holes 13 are illustrated as holes that are substantially rectangular as viewed from the XY plane.

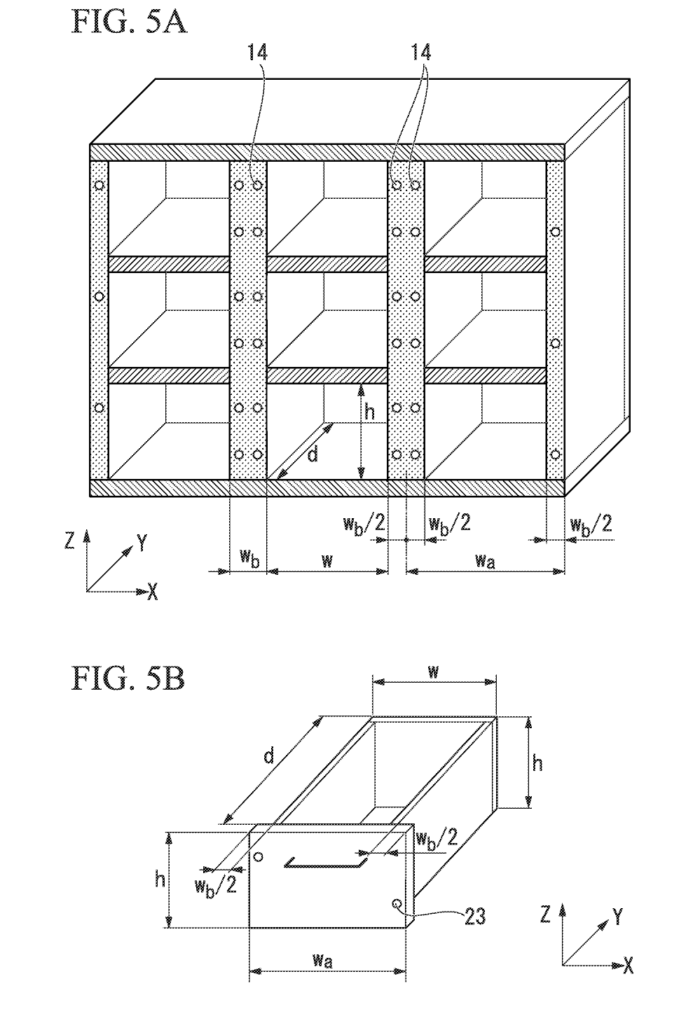

Additionally, the second partition plates 11 are side plates of the above compartments, have a predetermined thickness, and have a substantially rectangular shape as viewed from the YZ plane. Although the dimension of the predetermined thickness is greater than the diameter of housing screw holes 14 arranged at the positions of the second partition plates 11 corresponding to drawer screw holes 23 to be described below, the predetermined thickness may be a width in the X-direction that is enough to form only one housing screw hole 14. That is, unlike the related art, a width (a width dimension w_{b} shown in FIG. 5A) required to form two boosing screw holes 14 in the X-direction is unnecessary, and design is made so as to become a width (for example, a width dimension (w_{b}/2)) required to form one housing screw bole 14 in the X-direction while taking strength into consideration.

The first partition plates 10 or the second partition plates 11 are fixed to each other, or the first partition plates 10 or the second partition plates 11 are fixed to the back plate 4, the top plate 5, the bottom plate 6, or the side plates 9, to form the above compartments. Since this fixing is sufficient if the housing 2 can support the drawers 3 firmly when the drawers 3 to be described below are inserted into and arranged in the housing 2, these plates may be physically fitted and fixed to each other, for example, like an assembling block, or these plates may be fixed to each other with screwing or the like.

In addition, the above described fixing provides the structure such that a gap through which the above fluid flows is not substantially present in the respective compartments except in a vertical direction (Z-direction) by the vent holes 12a, 12b, and 13 and the above openings.

In FIG. 2, the first partition plates 10 are adapted so that one or two first partition plates are arranged in the above one compartment and are fixed as described above. However, according to the design, one or two common plates may be provided in the above three compartments that form one row (in this case, the vent holes 13 are formed corresponding to the compartments, respectively).

The second partition plate 11 is constituted as one common plate in the above three compartments that form one column, similarly to the side plates 9. However, a configuration in which division is made with the dimensions of each compartment in the height direction (Z-direction) may be adopted.

That is, the sizes of the first partition plates 10 and the second partition plates 11 are not necessarily matched with the dimensions of the above one compartment, and can be appropriately changed according to design. However, in a case where the first partition plate 10 is formed as one plate straddling the plurality of compartments, the vent holes 13 are formed in locations that become respective floor plates of the plurality of compartments (that is, the vent holes 13 of a number according to the number of compartments straddling one first partition plate 10 are formed).

In addition, although the above compartments are practical compartments surrounded by the back plate 4, the side plates 9 or the second partition plates 11, and the top plate 5, the bottom plate 6, or the first partition plates 10 except for the above openings, a configuration in which the drawers 3 are supported by the first partition plates 10 may not be adopted. That is, projections, rails, or the like for supporting the drawers 3 instead of the first partition plates 10 may be provided on the side plates 9 or the second partition plates 11 at the positions of the housing 2 where the first partition plates 10 are arranged may be appropriately arranged. In this case, the compartments are not formed practically when viewed in the column direction (Z-direction). However, partitions where the drawers 3 are inserted and arranged are still present clearly. Accordingly, the description will be continued, with the partitions continuously arranged in each column being imaginary compartments, respectively. That is, since the present invention also includes a storage unit of this shape, the description will be continued below supposing that both the practical compartments and the imaginary compartments are compartments and the housing 2 forms a plurality of compartments.

As shown in FIGS. 3A and 3B, the drawer 3 includes a drawer bottom plate 17 including a vent hole 18, a drawer back plate 21, a drawer side plate 22a, a drawer side plate 22b, and a drawer front plate 19 (including a first drawer front plate and a second drawer front plate adjacent to the first drawer front plate).

The drawer bottom plate 17 has a predetermined thickness, and has a substantially rectangular shape of the substantially same dimensions (w×d) as the above compartment on the XY plane as viewed from the XY plane. Additionally, the vent hole 18 (a second vent hole, a third vent hole) is provided at a position corresponding to the vent hole 13 or the vent hole 12b when the drawer 3 is inserted into and arranged in the above compartment and is pierced with the substantially same dimensions (w_{c}×d_{c}) as the vent hole 13 or the vent hole 12b (where 0<w_{c}<<w, 0<d_{c}<<d).

The drawer back plate 21 has a predetermined thickness, has a substantially rectangular shape of the substantially same dimensions (w×h) as the above opening as viewed from the XZ plane, and is connected to one side located on +Y-direction side out of two sides of the drawer bottom plate 17 that extend in the X-direction.

The drawer side plate 22a has a predetermined thickness, has a substantially rectangular shape as viewed from the YZ plane, and is connected to one side located on the +X-direction side out of two sides of the drawer bottom plate 17 that extend in the Y-direction and one side located on the +X-direction side out of two sides of the drawer back plate 21 that extend in the Z-direction.

The drawer side plate 22b has a predetermined thickness, has a substantially rectangular shape as viewed from the YZ plane, and is connected to one side located on the −X-direction side out of the two sides of the drawer bottom plate 17 that extend in the Y-direction and one side located on the −X-direction side out of the two sides of the drawer back plate 21 that extend in the Z-direction.

The drawer front plate 19 has a predetermined thickness, and is connected to one side located on the −Y-direction side out of the two sides of the drawer bottom plate 17 that extend in the X-direction and one side located on the −Y-direction side out of two sides of the drawer side pates 22a and 22b that extend in the Z-direction.

A handle 20 is attached to the drawer front plate 19, and a user can make the drawer 3 slide in the Y-direction with the handle 20 after the drawer is inserted into and arranged in one of the above compartments of the housing 2. Additionally, if the drawer 3 is inserted into the compartment and the drawer 3 is firmly closed and arranged, the storage unit 1 is designed so as to have the structure in which the drawer front plate 19 blocks the opening, and a gap through which a fluid, such as air, flows is not substantially present between the inside of the compartment and the opening.

Additionally, the drawer side plates 22 (22a and 22b) not only has the function of increasing the strength of the drawer 3, but also has the function of preventing dropping of the contents stored in the drawer 3 if the drawer 3 is pulled out of a corresponding compartment. Accordingly, the drawer side plates 22 (22a and 22b) are not necessarily plate-shaped, and may be a rod-shaped coupling member that couples the drawer front plate 19 and the drawer hack plate 21.

The shapes of the drawer front plates 19 that are altogether unified into the same shape in the storage unit 1 are designed so that the drawer front plates 19 of the drawers 3 inserted into the compartments adjacent to each other in the X-direction alternately fit each other like parquet or are alternately combined with each other, and the drawer front plates 19 do not overlap each other in the Y-direction. Moreover, the drawer front plates 19 are designed so that both the drawer front plates are fixed to the housing on both sides of their corresponding compartments.

FIG. 3A shows the shape of the drawer front plate 19 as a substantially N-type shape as an example. Specifically, the drawer front plate 19 has a substantially quadrangular portion (first portion) 19a of the substantially same size as the above opening, that is, of a dimension w in the X-direction and a dimension h in the Z-direction, and two substantially quadrangular portions (second portions) 19b and 19c of a dimension (w_{b}/2) in the X-direction and a dimension (h/2) in the Z-direction, and the first portion 19a and the second portions 19b and 19c have an integrally formed shape.

In order to obtain the above substantially N-type, one second portion 19b is connected to one side located on the +Z-direction side out of two sides of the first portion 19a that extend in the X-direction and is connected to one side located on the −X-direction side out of two sides of the first portion 19a that extend in the Z-direction. Additionally, the other second portion 19c is connected to one side located on the −Z-direction side out of the two sides of the first portion 19a that extend in the X-direction and is connected to one side located, on the +X-drrection side out of the two sides of the first portion 19a that extend in the Z-direction. Accordingly, the width dimension wₐ of the drawer front plate 19 in the X-direction becomes wₐ=w=2×(w_{b}/2).

One drawer screw hole 23 of a diameter D smaller than the dimension (w_{b}/2) is formed in the second portion 19b or 19c.

As described above, the housing screw holes 14 that are female screws of the same diameter D as the drawer screw holes 23 are formed at positions corresponding to the drawer screw holes 23 of the second partition plates 11 and the side plates 9 when the drawers 3 are inserted into the corresponding compartments.

Accordingly, nine drawers 3 shown in FIG. 3A are respectively inserted into the nine compartments of the housing 2. Thereby, as shown in FIG. 1, the two drawers 3 adjacent to each other in the X-direction across the one second partition plate 11 are brought into a state where the drawers alternately fit each other over the second partition plate 11 or are alternately combined with each other over the second partition plate such that the second portion 9b of one drawer 3 is located on the +Z-direction side and the second portion 19c of the other drawer 3 is located on the −Z-direction side. Specifically, in a second partition plate 11 that becomes a side wail of a compartment into which one drawer 3 is inserted as viewed from the XZ plane, the second portion 19b of the one drawer 3 substantially covers the whole surface of the second partition plate 11 from the middle point of the height h of the compartment in the Z-direction to the +Z-direction side, that is, the ceiling of the compartment. Additionally, in a second partition plate 11 that becomes a side wail of a compartment into which the other drawer 3 is inserted as viewed from the XZ plane, the second portion 19c of the other drawer 3 substantially covers the whole surface of the second partition plate 11 from the middle point of the height h of the compartment into which the drawer 3 is inserted in the Z-direction to the −Z-direction side, that is, the floor of the compartment. Accordingly, the drawer front plates 19 of the two drawers 3 do not overlap each other in the Y-direction.

Here, hereinafter, a state where the second portion 19b of one drawer of two drawers adjacent to each other across one partition plate and the second portion 19c of the other drawer alternately fit each other over the one partition plate (the first partition plate 10 or the second partition plate 11) or are alternately combined with each other over the partition plate and the second portions do not overlap each other is referred to as “fitting”.

For this reason, as shown in FIGS. 1 and 2, male screws 15 (where the diameter of a shank is a dimension D and the diameter of a head is larger than the dimension D) are screwed into the housing screw holes 14 formed only in one row in the Z-direction in the second partition plates 11 or into the housing screw holes 14 formed in the side plate 9 (9a, 9b), via the drawer screw holes 23 of the second portions. Thereby, the drawers 3 can be fixed to the housing on both sides of the compartments corresponding to the drawers 3. Accordingly, the drawers 3 can be effectively prevented from coming out of the compartments corresponding to the drawers 3, and the contents of the drawers 3 can be effectively prevented from spilling out of the storage unit 1.

Additionally, the interval between the compartments adjacent to each other in the X-direction can be reduced by half as compared to the housing of the related art shown in FIG. 5A irrespective of whether the dimensions of the compartments are the same. Here, at least the width dimension (w_{b}/2) of the second partition plates 11 can be set to (w_{b}/2)<2×D. Thereby, size reduction is realized such that the housing screw holes 14 formed in the second partition plates 11 are lined up only in one row in the Z-direction.

That is, the storage unit 1 has a shape in which the “fitting” between the structure of the housing 2 described above and the drawer front plates 19 is made. Thereby, size reduction is enabled without changing the capacity (about w×d) of the contents of the drawers 3 from the capacity (about w×d) of the contents of the drawers of the storage unit of the related art shown in FIGS. 5A and 5B by making the interval between the compartments of columns adjacent to each other small while adopting a fixing member that fixes the drawer front plates 19 to the housing 2 on both sides of the compartments corresponding to the drawers.

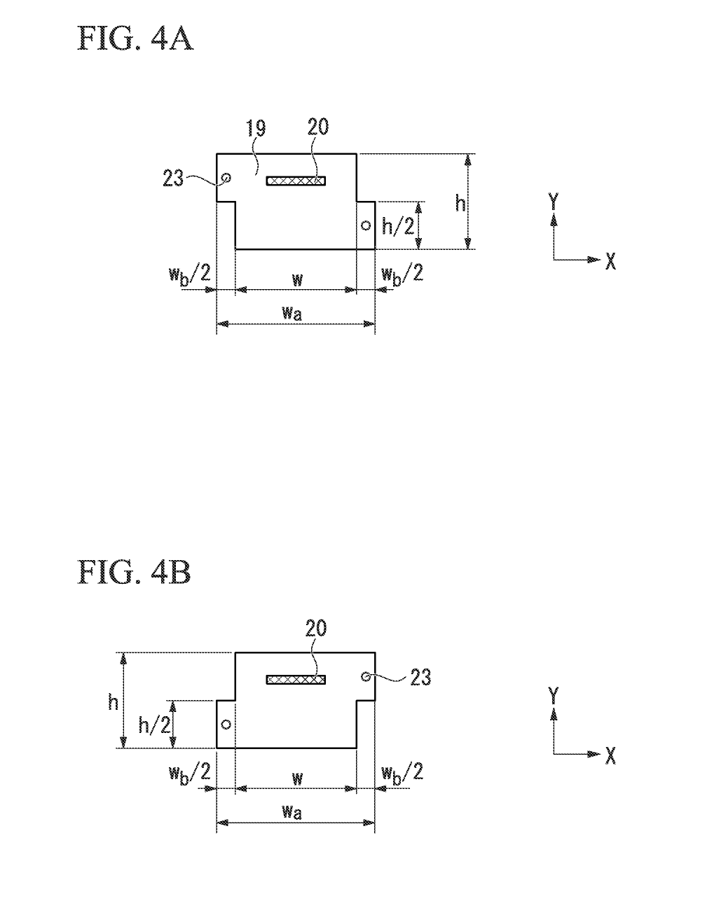

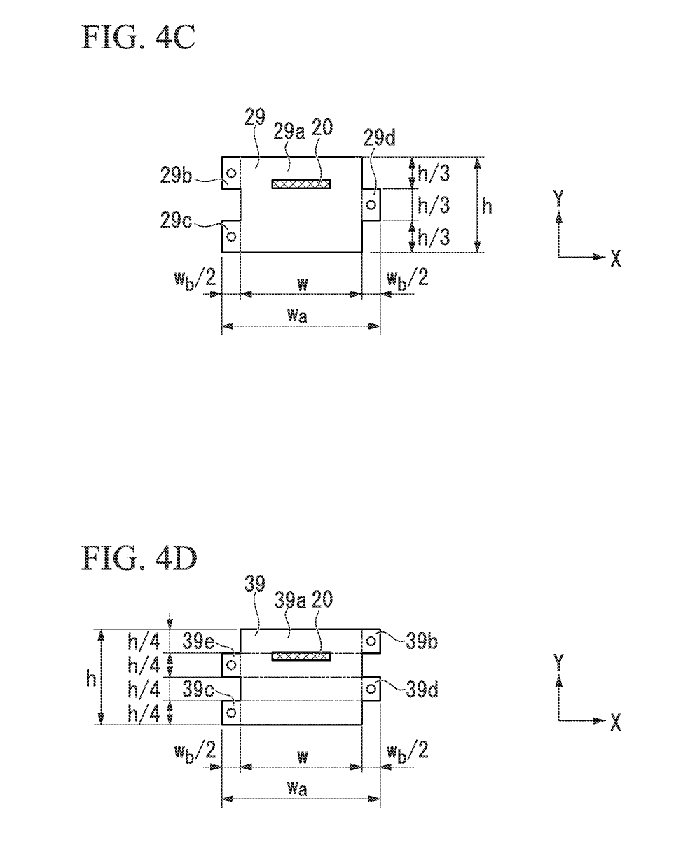

In the storage unit 1, although the shape of the substantially N-type shape is illustrated in FIG. 3A as the shape of the drawer front plates 19 that are altogether unified into the same shape, the “fitting” only needs to be performed. Accordingly, as shown in FIGS. 4C and 4D, a plurality of (two or more) second portions may be formed, and the same storage unit as the storage unit 1 may be adopted for the other configuration. In the case of a modified example of these storage units, the above-described housing screw holes 14 are formed at positions corresponding to the drawer screw holes 23 of respective drawer front plates of FIGS. 4C and 4D in the housing 2.

For example, although the drawer front plate of FIG. 4A is the same as the drawer front plate 19 shown in FIG. 3A, as shown in FIG. 4B, a substantially N-type shape that is line-symmetrical to the shape of FIG. 4A on the Z-axis may be adopted.

Additionally, as shown in FIG. 4C, the drawer front plate 29 may have three second portions 29b, 29c, and 29d. Specifically, a substantially quadrangular portion (first portion) 29a of the substantially same size as the above opening, that is, of a dimension w in the X-direction and a dimension h in the Z-direction, and three substantially quadrangular portions (second portions) 29b, 29c, and 29d of a dimension (w_{b}/2) in the X-direction and a dimension (h/3) in the Z-direction may have an integrally formed shape. In this case, one second portion 29b is connected to one side located on the +Z-direction side out of two sides of the first portion 29a that extend in the X-direction and is connected to one side located on the −X-direction side out of two sides of the first portion 29a that extend in the Z-direction. Another second portion 29c is connected to one side located on the −Z-direction side out of the two sides of the first portion 29a that extend in the X-direction and is connected to one side located on the −X-direction side out of the two sides of the first portion 29a that extend in the Z-direction. The third second portion 29d is connected to one side located on the +X-direction side out of the two sides of the first portion 29a that extend in the Z-direction, from a position advanced by a dimension (h/3) in the Z-direction from one side located on the +Z-direction side out of the two sides of the first portion 29a that extend in the X-direction, to a position advanced by the dimension (h/3) in the +Z-direction from the other one aide located on −Z-direction side. One drawer screw hole 23 of a diameter D smaller than the dimension (w_{b}/2) is formed in each of the second portions 29b, 29c, and 29d.

Since the shape of FIG. 4C allows the number of the male screws 15 for fixation to the housing 2 to be increased one more than the shape of FIG. 4A or FIG. 4B, the drawer 3 can be more effectively prevented from coming out of the corresponding compartment. Additionally, the contents of the drawer 3 can be more effectively prevented from spilling out of the storage unit 1.

In addition, the same effects are also obtained by a shape that is line-symmetrical to the shape of FIG. 4C on the Z-axis.

Moreover, as shown in FIG. 4D, the drawer front plate 39 may have four second portions 39b, 39c, 39d, and 39e. Specifically, a substantially quadrangular portion (first portion) 39a of the substantially same size as the above opening, that is, of a dimension w in the X-direction and a dimension h in the Z-direction, and four substantially quadrangular portions (second portions) 39b, 39c, 39d, and 39e of a dimension (w_{b}/2) in the X-direction and a dimension (h/4) in the Z-direction may have an integrally formed shape. In this case, one second portion 39b is connected to one side located on the +Z-direction side out of two sides of the first portion 39a that extend in the X-direction and is connected to one side located on the +X-direction side out of two sides of the first portion 39a that extend in the Z-direction.

Another second portion 39c is connected to one side located on the −Z-direction side out of the two sides of the first portion 39a that extend in the X-direction and is connected to one side located on the −X-direction side out of the two sides of the first portion 39a that extend in the Z-direction.

The third second portion 39d is connected to one side located on the +X-direction side out of the two sides of the first portion 39a that extend in the Z-direction, from a position advanced by a dimension 2×(h/4) in the −Z-direction from one side located on the +Z-direction side out of the two sides of the first portion 39a that extend in the X-direction, to a position advanced by the dimension (h/4) in the +Z-direction from the other one side located on −Z-direction side.

The fourth second portion 39e is connected to one side located on the −X-direction side out of the two sides of the first portion 39a that extend in the Z-direction, from a position advanced by a dimension, (h/4) in the −Z-direction from one side located on the +Z-direction side out of the two sides of the first portion 39a that extend in the X-direction, to a position advanced by the dimension 2×(h/4) in the +Z-direction from the other one side located on −Z-direction side. One drawer screw hole 23 of a diameter D smaller than the dimension (w_{b}/2) is formed in each of the second portion 39b, 39c, 39d, and 39e.

Since the shape of FIG. 4D allows the number of the male screws 15 for fixation to the housing 2 to be increased two more than the shape of FIG. 4A or FIG. 4B, the drawer 3 can be more effectively prevented from coming out of a corresponding compartment. Additionally, the contents of the drawer 3 can be more effectively prevented from spilling out of the storage unit 1. Moreover, the shape of FIG. 4C is a shape in which the drawer 3 is asymmetrically fixed to the housing 2 in two locations at one end of the drawer 3 in the X-direction and in one location at the other end. Thereby, as in the shape of FIG. 4D, if the drawer 3 is symmetrically fixed to the housing 2 in two locations at one end of the drawer 3 in the X-direction and in two locations at the other end, fixation reliability becomes higher. Accordingly, the shape of FIG. 4D is more excellent from a viewpoint of fixation of the drawer 3 to the housing 2 even if compared to die shape of FIG. 4C. Additionally, the same effects are also obtained by a shape that is line-symmetrical to the shape of FIG. 4D on the Z-axis.

Although the effects of the storage unit 1 of the present embodiment that enables sizes reduction or the like has been described above, since the configuration of the storage unit 1 is a configuration that forms the “chimney-like passage” to be described below, an excellent effect is also exhibited in the temperature control of contents stored in the drawers 3 in addition to the above-described effects.

Specifically, by inserting the drawers 3 into the housing 2 and firmly shutting the above openings, a flow channel along which a fluid, such as air, flow out of the vent hole 12a of the top plate 5 substantially through only a plurality of compartments arranged in each column of the storage unit 1 via the vent holes 18 of the drawers 3, or its reverse flow channel, can be formed. That is, a space (referred to as “chimney-like passage”) in which each column in the Z-direction resembles one chimney can be provided.

Accordingly, in a case where contents are heating elements, such as electronic devices, for example, a battery module, and the storage unit 1 is arranged in the atmosphere, the air that got warm due to heat generation goes upwards (+Z-direction). As a result, the flow of the fluid that escapes from a lower compartment to an upper compartment in the column, and further to the vent hole 12a of the top plate 5 is naturally generated. In the case, since one column is a chimney-like passage, the flow rates of the fluid that flows through the respective compartments arranged in one column becomes all the same. Accordingly, even the blowers 16 respectively arranged under the vent holes 12b of the lowest compartments of the respective columns are not driven, the low-temperature fluid that flows in from a lower portion of the chimney-like passage via the vent hole 8 of the platform 7 can be effectively brought into contact with the contents of the respective compartments, and can be sufficiently heat-exchanged therewith. For this reason, the cooling effect of the contents arranged in the respective compartments can be improved as a result.

Of course, the blowers 16 can he driven to form the flow of a fluid forcedly. In this case, it is possible to more effectively perform the above heat exchange.

Additionally, if the second partition plates 11 are made of a heat-insulating material in order to prevent the heat conduction between the respective columns, the heat distribution of the respective columns can be equalized. Accordingly, in a case where battery modules or the like of the same configuration are arranged in the respective compartments of the storage unit 1 and are handled as one battery system, the control or repair thereof can be made easy.

Additionally, a configuration may be adopted in which the blowers are connected to an air intake duct, and the vent holes 12a of the top plate 5 are connected to an exhaust air duct, and a cooling-effect gas or the like other than air is made to flow as the above fluid. Additionally, the blowers 19 may be arranged at the highest stages of the respective columns, or may be arranged at both the lowest stage and the highest stage. Depending on design, the blowers may be connected to the exhaust air duct and the vent holes 12a of the top plate 5 may be connected to the air intake duct.

In addition, in the above storage unit 1, the material of the housing 2 only needs to have the strength of supporting the drawers 3, and may be not only metal but also tree, resin, or the like. Additionally, the material of the drawers 3 also only needs to have the strength of firmly supporting the contents arranged inside the drawers 3, and may be not only metal but also tree, resin, or the like.

In order to make the sliding of the drawers 3 easy, the housing 2 or the drawers 3 may be appropriately provided with guide rails, rollers, or the like.

Additionally, when contents are held or arranged inside a drawer 3, it is necessary to take Into consideration so that the contents do not block the vent hole 18 formed through the drawer bottom plate 17, or so that the contents may not drop out of the vent hole 18. In terms of the structure of contents, in a case where the contents are held in a drawer 3 as it is to block the vent hole 18 or in a case where the contents drop out of from the vent hole 18, in order to secure a gap through which a fluid that enters the drawer 3 from the vent hole 18 flows or retain the contents inside the corresponding drawer, a supporting base that supports the contents while the contents are floated by a constant distance from the drawer bottom plate 17 is appropriately arranged, or the supporting base is formed integrally with the drawer bottom plate 17.

As described above, according to the storage units of the above embodiment or the modified examples, size reduction is enabled without changing the amount of the contents of the drawers from the amount of the contents of the drawers of the storage unit of the related art by making the interval between the compartments of columns adjacent to each other small while adopting the fixing member that fixes the drawer front plates to the housing on both sides of the corresponding compartments. Moreover, the contents stored in the drawers respectively arranged in a plurality of compartments of the housing can be substantially equally controlled in temperature, for example, substantially equally cooled by making the above chimney-like passage.

Additionally, the present invention is not limited to the above-described embodiment and the modified examples thereof, and various alternations can be made departing from the concept of the present invention.

For example, a case where the drawers 3 and the housing 2 are fixed by the male screws 15 as the fixing member on both sides of the corresponding compartments in the X-direction has been described. However, a configuration in which the drawers and the housing may be fixed on both sides in the Z-direction may be adopted. In this case, the housing screw holes 4 may be appropriately formed in the top plate 5, the first partition plates 10 of which the thickness is the dimension (w_{b}/2), or the bottom plate 6, drawers each having a drawer front plate in a state where the drawer front plate shown in FIGS. 4A to 4D is rotated by 90 degrees in the XZ plane may be prepared, and the same configuration as the above-described storage unit 1 may be adopted for the other configuration. Such a state is also a state where the drawer front plates are fixed to the housing on both sides of the corresponding compartments, and, can also be referred to as “fitting”.

Additionally, although the male screws 15 and the housing screw holes 14 (female screws) are illustrated as the fixing members, the fixing members may be pins and holes corresponding thereto.

Moreover, in the embodiment and the modified examples thereof, the drawer from plates used for the storage unit 1 have all the same shape from viewpoints of easy manufacture and cost reduction. However, as long as a configuration that enables to fit in which the size reduction of a storage unit is enabled while fixing the drawer front plates to the housing on both sides of the corresponding compartments is provided, the shapes of drawer front plates of drawers to be inserted into compartments of one storage unit may be a plurality of (two or more) types of shape. For example, two types of drawer front plates of a shape in which the first portion 19a of FIG. 4A, and the two quadrangular portions (second portions) 19b and 19c of a dimension (w_{b/2}) in the X-direction and a dimension (h/2) in the Z-direction are integrally formed may be alternately adopted in every column. Specifically, for example, the shape of a first type of drawer front plates is as follows. That is, a configuration is provided in which one second portion is connected to one side located on the +Z-direction side out of the two sides of the first portion that extend in the X-direction and is connected to one side located on the −X-direction side out of the two sides that extend in the Z-direction of the first portion, and the other second portion is connected to one side located on the +Z-direction side out of the two sides of the first portion that extend in the X-direction and is connected to one side located on the +X-direction side out of the two sides of the first portion that extends in the Z-direction. Additionally, the shape of a second type of drawer front plates is as follows. That is, a configuration may be provided in which one second portion is connected to one side located on the −Z-direction side out of the two sides of the first portion that extend in the X-direction and is connected to one side located on the −X-direction side out of the two sides that extend in the Z-direction of the first portion, and the other second portion is connected to one side located on the −Z-direction side out of the two sides of the first portion that extends in the X-direction and is connected to one side located on the +X-direction side out of the two sides of the first portion that extends in the Z-direction.

Moreover, if the above chimney-like passage can be made, and the temperature control of contents, for example, cooling, can be effectively performed, the shape of the respective vent holes is not limited to the substantially rectangular shape, and may be shapes, such as a circular shape or a triangular shape. Additionally, since the heating elements are illustrated here as the contents, cooling is taken as an example as the temperature control. However, the temperature control described here is not limited to air conditioning or cooling, and includes the concepts of heating, warming, drying, or the like according to environments and contents in which storage units are placed.

### INDUSTRIAL APPLICABILITY

According to the above, it is possible to provide a storage unit in which size reduction is enabled without changing the amount of the drawers from the amount of the drawers of the storage unit of the related art by making the interval between the compartments of columns adjacent to each other small while fixing the drawer front plates to the housing on both sides of the corresponding compartments.

### Reference Signs List

1: STORAGE UNIT

2: HOUSING

3: DRAWER

4: BACK PLATE

5: TOP PLATE

6: BOTTOM PLATE

7: PLATFORM

8: VENT HOLE (FOR PLATFORM)

9: SIDE PLATE

10: FIRST PARTITION PLATE

11: SECOND PARTITION PLATE

12 (12A, 12B): VENT HOLE (FOR TOP PLATE OR BOTTOM PLATE)

13: VENT HOLE (FOR FIRST PARTITION PLATE)

14: HOUSING SCREW HOLE (FEMALE SCREW)

15: SCREW (MALE SCREW)

16: BLOWER (FAN)

17: DRAWER BOTTOM PLATE

18: VENT HOLE (FOR DRAWER)

19: DRAWER FRONT PLATE

20: HANDLE

21: DRAWER BACK PLATE

22 (22A, 22B): DRAWER SIDE PLATE

23: DRAWER SCREW HOLE

1. A storage unit comprising:
a first drawer which has a first drawer front plate;
a second drawer which has a second drawer front plate;
a housing which has a partition plate for partitioning a first compartment into which the first drawer is inserted and a second compartment into which the second drawer is inserted; and
a fixing member,
wherein the first drawer front plate and the second drawer front plate alternately fit each other on the partition plate and are arranged on partition plate without overlapping when viewed from a front of the first drawer and the second drawer, and the first drawer front plate and the second drawer front plate are respectively fixed to the housing on both sides of the first compartment or on both sides of the second compartment, using the fixing member.

2. The storage unit according to claim 1, further comprising:
a third compartment arranged continuously with the first compartment; and
a third drawer inserted into the third compartment,
wherein the housing has a first vent hole in an outer frame of the housing;
wherein the first drawer has a second vent hole,
wherein the third drawer has a third vent hole,
wherein the first drawer and the third drawer are inserted into the housing to form a chimney-shaped space,
wherein the flow rates of a fluid that flows through the first vent hole, the second vent hole, and the third vent hole by the chimney-shaped space are the substantially same.

3. The storage unit according to claim 2,
wherein the first drawer front plate and the second drawer front plate have the substantially same shape.

4. The storage unit according to claim 3,
wherein the housing has a blower, and the fluid is made to flow to the chimney-like passage.

5. The storage unit according to claim 2, wherein the fluid is air.
